(19) United States
(12) Patent Application Publication
(10) Pub. No.: US 2001/0051438 A1
(43) Pub. Date: Dec. 13, 2001

(54) Process and apparatus for dry-etching a semiconductor layer

(75) Inventors: Kyoung-Sub Shin, Sungnam-shi (KR); Kyeong-Koo Chi, Suwon (KR)

Correspondence Address: MARGER JOHNSON & MCCOLLOM PC, 1030 SW MORRISON STREET, PORTLAND, OR, 97205, US

(73) Assignee: Samsung Electronics, Suwon-City (KR)

(21) Appl. No.: 09/832,426

(22) Filed: Apr. 10, 2001

Related U.S. Application Data
(62) Division of application No. 09/104,463, filed on Jun. 24, 1998, now abandoned.

(30) Foreign Application Priority Data
Jun. 25, 1997 (KR) 97-27274

(51) Int. Cl. H01L 21/302; H01L 21/461

(52) U.S. Cl. 438/706; 438/707

(57) ABSTRACT

The present invention relates to a process and apparatus for dry-etching a semiconductor substrate or a layer formed on the substrate using a photoresist pattern having an opening, said process comprising the steps of forming a plasma in an etching chamber by applying a source of RF power to one of two electrodes in the etching chamber; applying a source of RF bias power to the other of the two electrodes in the etching chamber, wherein the other of the two electrode is provided to support the semiconductor substrate; and enabling the sources of the RF power and RF bias power to be periodically turned on/off to have a phase difference therebetween. An upper edge portion at both sidewalls of the opening of the photoresist pattern is not etched and at the same time a polymer is formed on the upper edge portion to obtain critical dimension of an etched portion corresponding to the opening.

In accordance with the process and apparatus for dry-etching a semiconductor layer of the present invention, critical dimension of the upper edge portion can be maintained by turning the RF power and RF bias power on and off to have a phase difference therebetween. A bottom of the etched portion is formed narrower in critical dimension than a top of the etched portion when the amount of the polymer is increased.

This application is a divisional of U.S. patent application Ser. No. 09/104,463, filed on Jun. 24, 1998, now pending.

### FIELD OF THE INVENTION

The present invention relates to a process and apparatus for dry-etching a semiconductor layer. More particularly, the invention relates to a process and apparatus for dry-etching a semiconductor layer in which contact holes having a critical dimension of less than approximately 0.25 μm can be formed by periodically turning on and off an RF power source and a RF bias power to create a phase difference therebetween by time modulation.

### BACKGROUND OF THE INVENTION

In fabricating semiconductor devices, processes for forming the devices has become increasingly difficult due to a higher integration of semiconductor devices.

The dry-etching process using a plasma source requires the use of a low pressure high density plasma source to form a micro pattern adhereing to a design specification of less than a quarter micron. The low pressure high density plasma source has a high etch rate by maintaining a density of more than 10¹¹ cm⁻³ even at several millitorr or lower, and therfore a high anisotropy etching process can be executed. In most cases, since a RF power is separated from a RF bias power which is applied to the semiconductor substrate, there is the advantage that the energy of introduced ions to the semiconductor substrate is controlled independently. Accordingly, the low pressure high density plasma source is now widely used.

Examples of the low pressure high density plasma source include ICP (Inductively Coupled Plasma), ECR (Electron Cyclotron Resonance), Helicon, SWP (Surface Wave Plasma) and others. New high density sources are now being developed.

Problems of the above described low pressure high density plasma source include a notching phenomenon which occurs due to a narrow processing region, a high electron temperature resulting from the low pressure processing, and a low selectivity which occurs due to a high degree of dissociation, among others.

In order to solve the previously mentioned problems, hardware improvements have been considered and efforts to develop a new gas chemistry on going.

In general, when an oxide layer contact is etched, a selectivity is controlled by using CFx group polymers. It is known that when a higher C/F ratio is used, a higher selectivity is achieved. However, since the low pressure high density plasma source has a high degree of dissociation, the C/F ratio is hardly increased. Consequently, a problem of low selectivity results.

To avoid the problem, a gas with a high C/F ratio may be used or alternatively a process is progressed in the downstream region having a low degree of dissociation.

FIG. 1 is a wave form chart generated by an oscilloscope measuring sources of RF power and RF bias power according to a prior art process for dry-etching a semiconductor device. FIGS. 2A to 2C are drawings illustrating sequential processes for forming the contact hole of the semiconductor layer according to the power condition of FIG. 1 with time passing.

Referring to FIG. 1, it is known that both of RF power and RF bias power according to the conventional process for dry-etching a semiconductor device use a high continuous wave.

The results of forming a contact hole on an insulating layer by the RF power and RF bias power are as follows.

First, as a sample for forming a contact hole 16, a BPSG oxide layer 12 of approximately 11,000 A thick is formed on a semiconductor substrate 10. A formed MLR (Multi-Layer Resist) pattern is then used on the oxide layer 12. The MLR pattern has a structure whose upper oxide layer has a thickness of 1,400 A and lower photoresist pattern 14 has a thickness of 8,000 A.

The critical dimension of the contact hole 16 which is defined by the pattern is 0.2 μm. At this time, the pressure condition of the plasma chamber is 3 millitorr, and the sources of RF power and the RF bias power have approximately 800 Watts and 200 Watts, respectively. As an etching gas of the oxide layer 12, a mixing gas of 15C₄F₈ and 35Ar may be used.

Referring to FIG. 2A, when the oxide layer 12 is etched by using the above mentioned pressure and power conditions and the etching gas, the photoresist pattern 14 is somewhat etched and its thickness is decreased. In particular, there exists an erosion phenomenon so that the upper edge portion at both sidewalls of the contact hole 16 of the photoresist pattern is etched and slightly tilted from its center to the outside.

FIG. 2B shows a process for forming a contact hole 16 when an oxide layer 12 is etched for 4 minutes. Since the thickness of a photoresist pattern 14 is decreased and the erosion of the photoresist pattern 14 at both sidewalls of the contact hole 16 is deepened, the lower portion of the oxide layer 12 is etched and upper critical dimension is somewhat increased.

FIG. 2C shows a process for forming a contact hole 16 when an oxide layer 12 is etched for 5 minutes and 50 seconds. Since the thickness of a photoresist pattern 14 is considerably decreased compared to FIG. 2B and the erosion of the photoresist pattern 14 at both sidewalls of the contact hole 16 is exceedingly deepened, and it cannot be also used smoothly as a mask, the upper critical dimension of the contact hole 16 is denoted as a1′ which is doubled, compared to that which is denoted a1 of FIG. 2A.

As described above, the conventional processes for dry-etching a semiconductor have a number of problems. Particularly, the ultra micro pattern is difficult to etch because upper critical dimension of the contact hole 16 is increased by the erosion of the photoresist pattern 14.

### SUMMARY OF THE INVENTION

The present invention is intended to solve the above-described problems. It is an object of the invention to provide a process for dry-etching a semiconductor layer and an apparatus for preventing the erosion of the photoresist pattern of an etched portion, so as to maintain or decrease the upper critical dimension of the etched portion.

It is another object of the present invention to provide a process for dry-etching a semiconductor layer and an apparatus for turning periodically on/off the RF power and the RF bias power, adhering a polymer to the photoresist pattern by controlling the phase difference, so that the critical dimension of the etched portion can be maintained, and the micro pattern of approximately 0.1 μm can be etched by controlling the amount of the polymer.

### BRIEF DESCRIPTION OF THE DRAWINGS

This invention may be understood and its objects will become apparent to those skilled in the art by reference to the accompanying drawings as follows:

FIG. 1 is a wave form chart generated by using an oscilloscope measuring sources of RF power and RF bias power according to a prior art process for dry-etching a semiconductor device;

FIGS. 2A to 2C are drawings illustrating sequentially processes for forming the contact hole of the semiconductor layer according to the power condition of FIG. 1 with time passing;

FIG. 3 is a wave form chart showing the phase difference condition of the RF power and the RF bias power of a process for dry-etching a semiconductor according to an example of the present invention;

FIGS. 4 to 5 are drawings illustrating sequentially with time processes for forming the contact hole of the semiconductor layer according to the power condition of FIG. 3; and

FIG. 6 is a block diagram showing the configuration of the semiconductor layer of an example of the present invention.

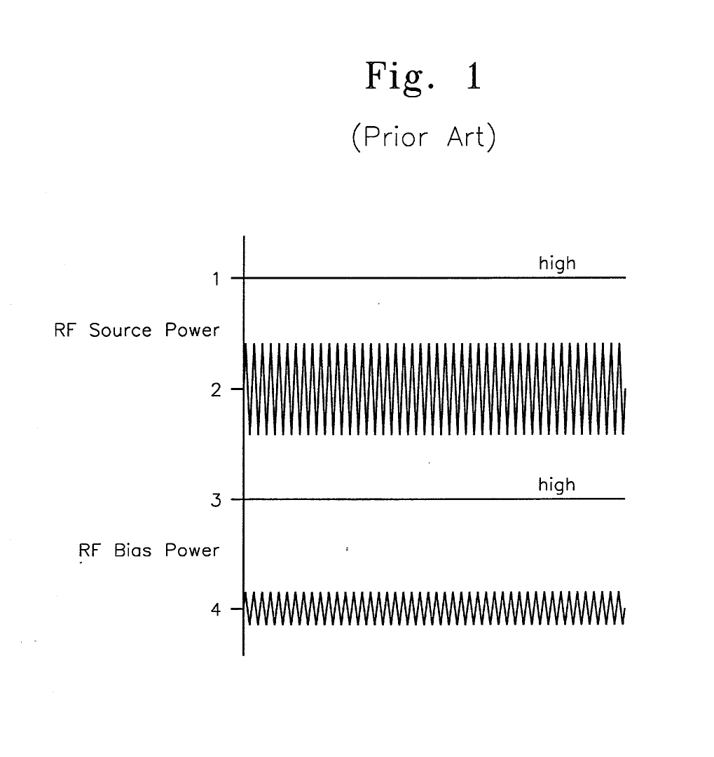

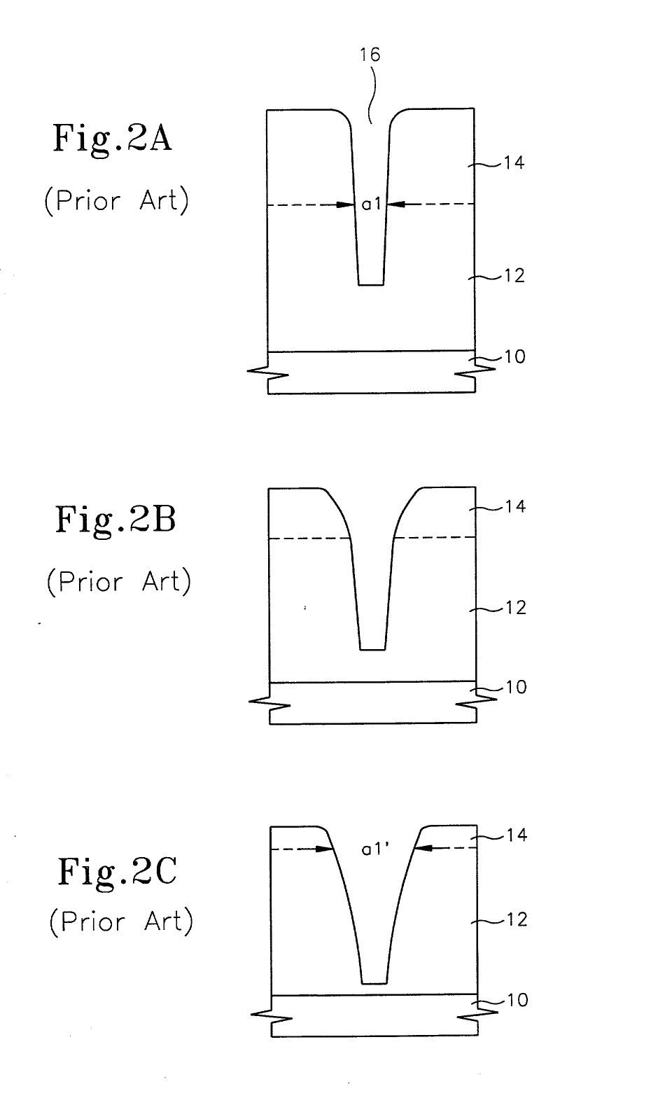

### DETAILED DESCRIPTION OF PREFERRED EMBODIMENTS

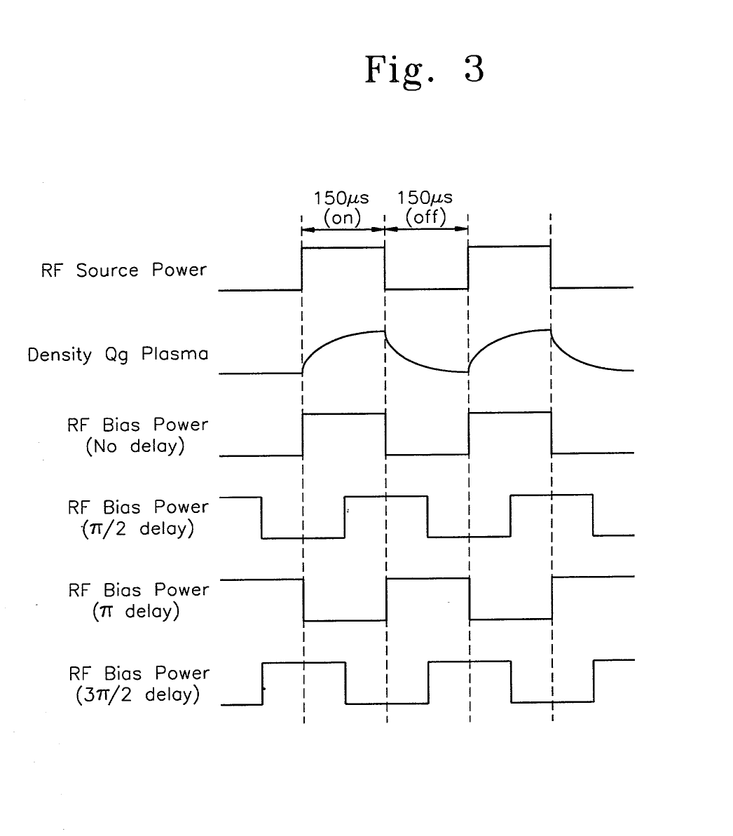

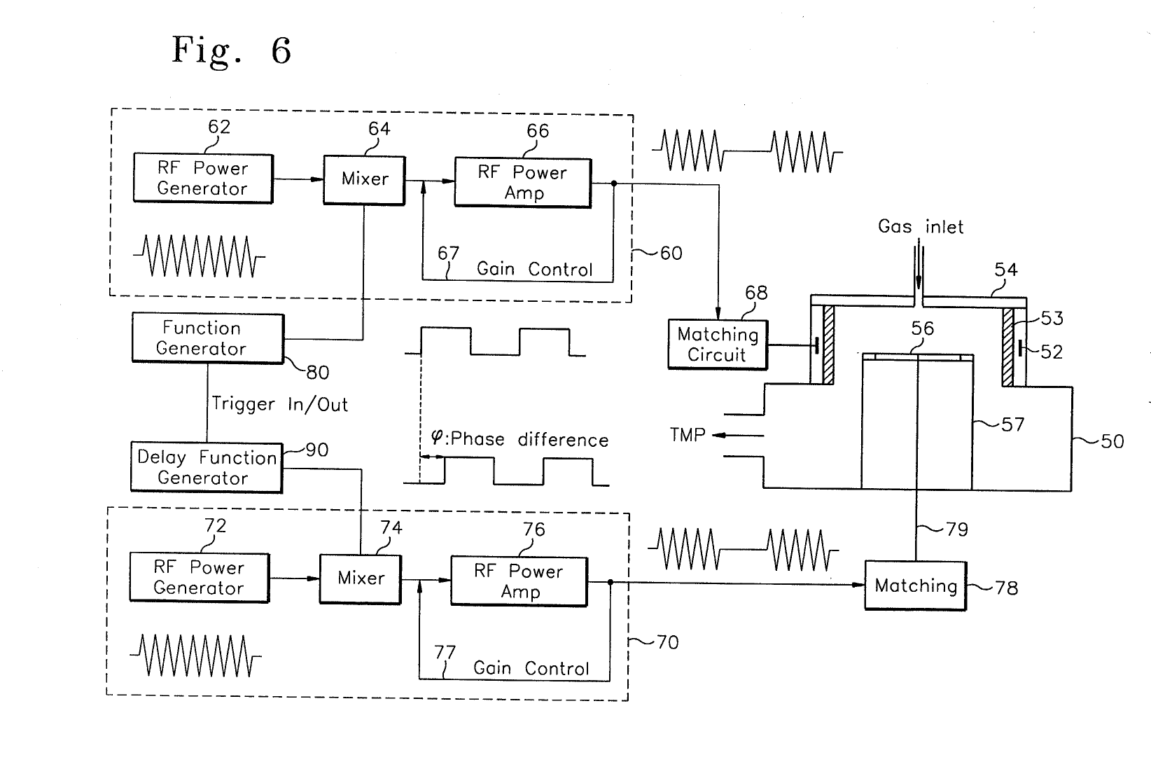

The preferred embodiments of the present invention will be discussed below in detail with reference to FIGS. 3 to 6. FIG. 6 is a block diagram showing the configuration of the semiconductor layer of an example of the present invention.

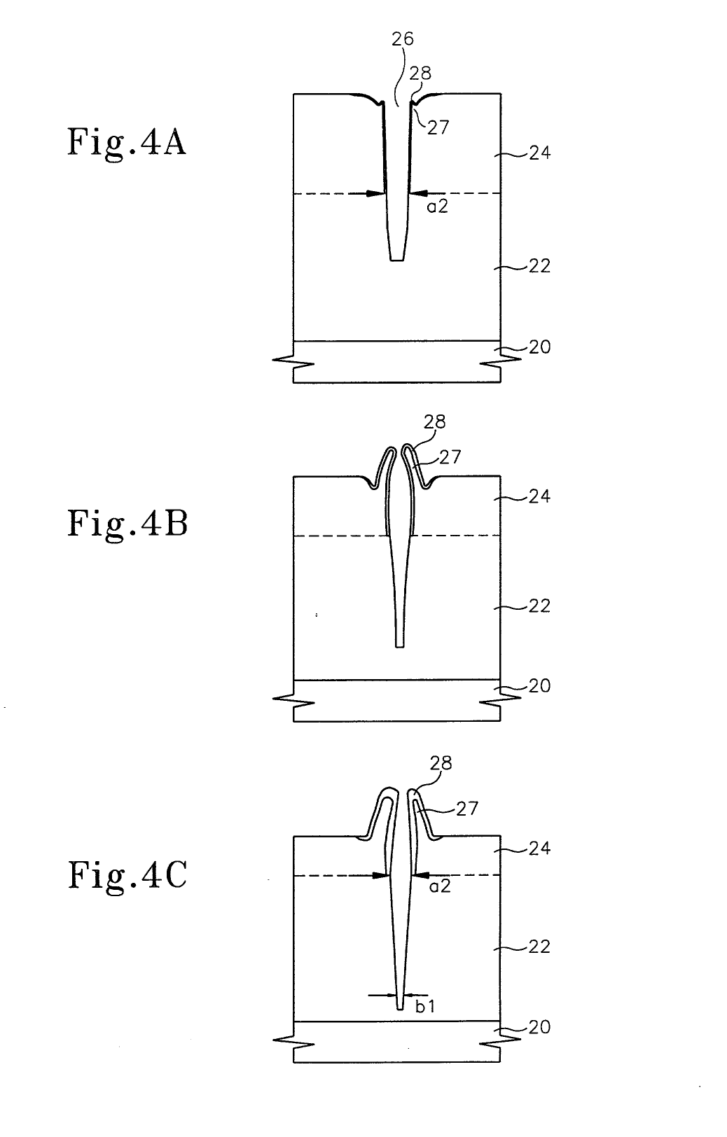

Referring to FIG. 6 and FIGS. 4A-4C, an apparatus for plasma etching a semiconductor layer according to the example of the present invention comprises a plasma etching chamber 50, an RF power supply 60, an RF bias power supply 70, a function generator 80, a delay function generator 90 and matching circuits 68 and 78. The apparatus for plasma etching a semiconductor layer can etch a semiconductor substrate 20 or a layer formed on the substrate 20, for example an oxide layer 22 formed on the substrate 20 by using a low pressure high density plasma source. At this time, the photoresist pattern 24 is formed on the substrate 20 in order to expose the etched portion of the substrate 20 or the oxide layer 22. The substrate 20 or the oxide layer 22 can be etched by using the pattern 24 as a mask. The low pressure high density plasma source is selected from a group including but not limited to ICP, ECR, Helicon, and SWP. ICP source is used in the example.

In a plasma etching chamber 50, an electromagnetic induction coil 52 such as wound copper is one of two electrodes around a ceramic chamber wall 53 of a cylinder shape. The substrate support 56 for supporting the semiconductor substrate 20 is positioned on the upper portion of the cylinder 57 in the chamber 50 as the other of the two electrodes. The support 56 is located under 3 cm from the plane on which the coil is located.

A plasma etching gas introduced through the gas inlet of aluminum plate on the upper portion of the chamber 50 is exhausted out of the chamber 50 by a Turbo Molecular Pump (TMP) after completion of the reaction.

The RF power supply 60 is electrically connected to the coil 52 and provides the RF power of 13.56 MHZ to the chamber 50 so as to generate the plasma in the chamber 50. The supply 60 comprises a RF power generator 62, a mixer 64, a RF power amplifier 66, and a gain control feedback loop 67. In addition, The supply 60 outputs the RF power which is generated from the RF power generator 62 and the modulated wave form having a predetermined period generated from the function generator 80 in the mixer 54 through the RF power amplifier 66 after time modulation (hereinafter, referred to as TM). At this time, the source of RF power outputted through the RF power amplifier 66 turns the RF power which is turned on and off during a predetermined period.

The RF bias power supply 70 is connected electrically to the substrate support 56 and provides the RF power of 13.56 MHZ to the chamber 50. The supply 70 comprises a RF generator 72, a mixer 74, a RF power amplifier 76, and a gain control feedback loop 77 similar to the RF power supply 60. The mixer 74 receives the modulated wave form generated from the delay function generator 90, and this modulated wave form is delayed to form the phase difference ψ from the modulated wave form generated from the function generator 80. The phase difference ψ is 0, π/2, π, 3π/2 and others in accordance with the present invention.

The RF bias power outputted through the RF power amplifier 76 turns the RF power on and off during a predetermined period. The source of RF power is applied to the electromagnetic induction coil through a matching mean 68, and the RF bias power is applied to the substrate support 56 through a matching mean 78.

FIG. 3 is a wave form chart showing the phase difference condition of the RF power and the RF bias power of a process for dry-etching a semiconductor according to an example of the present invention.

Referring to FIG. 3, the phase difference conditions of the RF power and RF bias power according to the process for dry-etching a semiconductor layer of the example of the present invention include a case which the RF bias power is not delayed with respect to the source of RF power, and cases which the RF bias power is delayed by π/2, π and 3π/2. Each of the modulated wave forms on the phase difference conditions is illustrated in FIG. 3.

At this time, the period of the RF power and RF bias power is used from several decades μs to several hundred μs. In this example, TM is performed by using the period of the RF power and the RF bias power of 300 μs and a duty ratio of 50%, respectively. That is, each of the RF power and the RF bias power is turned on for 150 μs, and turned off for 150 μs.

When the RF power and the RF bias power is turned on or off, the density of a plasma is increased or decreased, respectively. At this time, the source of RF power with respect to the phase difference condition between the RF power and the RF bias power is approximately 1600 Watts, the RF bias power therebetween is approximately 400 Watts. These values are applied in an amount twice that of a conventional RF power and RF bias power in order to agree with the total net power of a prior art device. The pressure of the chamber 50 is 3 millitorr. The etching gas for the oxide layer 22 is used as a mixing gas of 15C₄F₈ and 35Ar.

If the RF bias power is not delayed with respect to the source of RF power, when the contact hole is formed on the oxide layer 22 by using the photoresist pattern 24 as a mask, the upper critical dimension of the contact hole is increased in proportion to an increase in etching time in the same manner as in the prior art.

In other wards, the photoresist pattern 24 at both of the sidewalls of the contact hole can be etched during the etching of the oxide layer 22 in the region forming the contact hole, so that the critical dimension of the contact hole can be increased.

Such a phenomenon appears similarly in the case which the RF bias power is delayed by π/2 about the RF power. However, if the RF bias power is delayed by π or 3π/2 about the source of RF power, the upper critical dimension of the contact hole 26 is maintained.

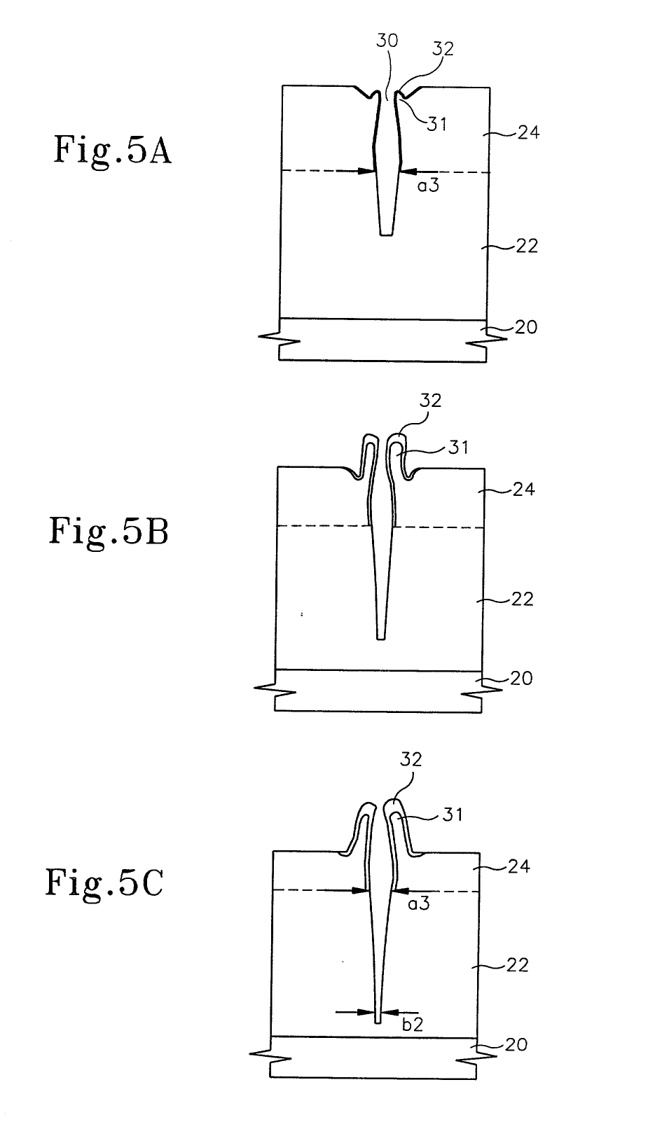

FIGS. 4A to 4C are drawings illustrating sequentially with time the processes for forming the contact hole 26 of the semiconductor layer according to the above π delay condition. FIGS. 5A to 5C are drawings illustrating sequentially with time the processes for forming the contact hole 30 of the semiconductor layer according to the above 3π/2 delay condition.

As a sample for forming the contact holes 26 and 30, a BoroPhospho Silicate Glass (BPSG) oxide layer 22 of approximately 11,000 A is formed on the semiconductor substrate 20 and, an Multi-Layer Resist (MLR) pattern is formed on the oxide layer. The MLR pattern has a structure that the upper oxide layer has a thickness of 1,400 A and the lower photoresist pattern has a thickness of 8,000 A. The critical dimension of the contact holes 26 and 30 defined by the pattern is 0.2 μm.

Referring to FIG. 4A, when the oxide layer 22 is etched for 5 minutes by using the above mentioned pressure, power, etching gas, and π delay condition in accordance with the apparatus for the semiconductor layer, the photoresist pattern 24 may be also somewhat etched. However, the photoresist pattern 24 at both sidewalls of the contact hole is almost not etched with respect to other portions of the photoresist pattern 24, so that the unetched photoresist pattern 27 remains in a mountain shape. A polymer 28 is thinly formed on the unetched photoresist pattern 27.

The unetched photoresist pattern 27, as illustrated in FIGS. 4B and 4C, is not etched even when each of etching times is increased to 10 minutes and 16 minutes and 13 seconds respectively, and the amount of the polymer 28 formed on the pattern 27 is increased gradually. Since the polymer 28 prevents the photoresist pattern 27 at both sidewalls of the contact hole 26 from eroding, the contact hole is formed toward the inlet in the proportion to the increase of etching time, so that the upper critical dimension a2 is maintained and the lower critical dimension b1 is formed relatively narrower. Thus, the contact hole having the critical dimension of 0.1 μm can be formed.

In addition, referring to FIG. 5, when the oxide layer 22 is etched for 4 minutes and 30 seconds by using the above mentioned pressure, power, etching gas, and 3π/2 delay condition, similar to the sample of the π delay condition, an unetched photoresist pattern 31 in a mountain shape remains at both sidewalls of the contact hole and a polymer 32 is formed on the pattern 31.

Referring to FIGS. 5B and 5C, when each of etching times is increased to 9 minutes and 16 minutes and 50 seconds respectively, the amount of the polymer 32 is increased, so that the upper critical dimension of the contact hole is maintained and the lower critical dimension b2 of the contact hole 30 is relatively formed narrower with respect to the upper critical dimension a3. Thus, the ultra micro pattern of approximately 0.1 μm can be etched by controlling the amount of the polymer 32 with respect to the π delay condition.

As above described, by the pulse plasma etching process which periodically turns the RF power and the RF bias power on and off and controls the phase difference, the contact holes 26 and 30 are formed while the upper critical dimensions a2 and a3 are maintained. Also, the ultra micro pattern can be etched by controlling the amount of the polymers 28 and 32 formed on the photoresist pattern 24.

Thus, the present invention is to solve the problem that the photoresist pattern is eroded and the upper critical dimension of the contact hole is increased in forming the contact hole using a conventional plasma etching process.

The process and the apparatus of the present invention provide an effect that the upper critical dimension of the contact hole can be maintained by turning on and off the RF power and the RF bias power and controlling the phase difference, and the critical dimension of the contact hole can be decreased by controlling the amount of the polymer formed on the photoresist pattern during a etching process.

What is claimed is:

1. A method for dry-etching a semiconductor substrate or a layer formed on the substrate using a photoresist pattern having an opening, said process comprising the steps of:
forming a plasma in an etching chamber by applying a source of RF power to one of two electrodes in the etching chamber;
applying a source of RF bias power to the other of the two electrodes in the etching chamber, wherein the other of the two electrode is provided to support the semiconductor substrate; and
enabling the sources of the RF power and RF bias power to be periodically turned on and off and to have a phase difference therebetween.

2. A method as recited in claim 1 wherein an upper edge portion of the sidewalls of the opening of the photoresist pattern is not etched, said method further comprising the following step:
forming a polymer on an upper edge portion.

3. A method as recited in claim 2 wherein said upper edge portion at at least one of the sidewalls of the opening of the photoresist pattern is not etched at the same time said polymer is formed.

4. A method as recited in claim 2, wherein said polymer is formed to obtain critical dimension of an etched portion corresponding to the opening.

5. A method as recited in claim 1, wherein said layer is an oxide layer.

6. A method as recited in claim 4, wherein said etched portion has critical dimension of less than approximately 0.25 μm.

7. A method as recited in claim 1, wherein the source of said RF power is a low pressure high density plasma source.

8. A method as recited in claim 7 wherein said low pressure high density plasma source is selected from a group consisting of ICP (inductively coupled plasma), ECR (electron cyclotron resonance), Helicon and SWP (surface wave plasma).

9. A method as recited in claim 1, wherein density of said plasma is increased and decreased by turning periodically on/off the source of said RF power.

10. A method as recited in claim 1, wherein each of the sources of said RF power and RF bias power has a period of approximately 300 μm and a duty ratio of approximately 50%.

11. A method as recited in claim 1, wherein said RF power and RF bias power have approximately 1600 Watts and 400 Watts in power level, respectively.

12. A method as recited in claim 1, wherein said RF bias power has a phase difference delayed from π to 3π/2 with respect to said RF power.

13. A method as recited in claim 2, wherein the amount of said polymer applied is increased in proportion to the phase difference between said RF power and RF bias power.

14. A method as recited in claim 3, wherein a bottom of said etched portion is formed narrower in critical dimension than a top of said etched portion when the amount of the polymer is increased.

15. A method for dry-etching a semiconductor substrate or a layer formed on the substrate using a photoresist pattern having an opening, said process comprising the steps of
avoiding etching an upper edge portion at the sidewalls of the opening of the photoresist pattern; and
forming a polymer is formed on the upper edge portion.

16. A method as recited in claim 16 wherein said avoiding step and said forming step occur substantially simultaneously.

17. A method as recited in claim 17 wherein said forming step provides a critical dimension of an etched portion corresponding to the opening.

18. A method as recited in claim 15, prior to said avoiding and forming step, said method further comprises the steps of:
forming a plasma in an etching chamber by applying a source of RF power to one of two electrodes in the etching chamber;
applying a source of RF bias power to the other of the two electrodes in the etching chamber, wherein the other of the two electrode is provided to support the semiconductor substrate; and
enabling the sources of the RF power and RF bias power to be periodically turned on and off and to have a phase difference therebetween.

19. A method as recited in claim 18, wherein the amount of said polymer applied is increased in proportion to the phase difference between said RF power and RF bias power.

20. A method as recited in claim 17, wherein a bottom of said etched portion is formed narrower in critical dimension than a top of said etched portion when the amount of the polymer is increased.
